(19) United States
(12) Patent Application Publication
(10) Pub. No.: US 2026/0202733 A1
(43) Pub. Date: Jul. 16, 2026

(54) REFLECTIVE PHOTOMASK AND METHOD FOR FABRICATING THE SAME

(71) Applicant: SAMSUNG ELECTRONICS CO., LTD., Suwon-si (KR)

(72) Inventors: Jung Youp KIM, Suwon-si (KR); Kwan Hee LEE, Suwon-si (KR)

(73) Assignee: SAMSUNG ELECTRONICS CO., LTD., Suwon-si (KR)

(21) Appl. No.: 19/288,185

(22) Filed: Aug. 1, 2025

(30) Foreign Application Priority Data
Jan. 15, 2025 (KR) 10-2025-0005940

(51) Int. Cl. G03F 1/24; G03F 1/52; G03F 1/54; G03F 1/72; G03F 1/80

(52) U.S. Cl. CPC G03F 1/24; G03F 1/52; G03F 1/54; G03F 1/72; G03F 1/80

(57) ABSTRACT

A method for manufacturing a reflective photomask for improved productivity includes providing a mask substrate including a pattern area and a black border area surrounding the pattern area, forming a reflective layer on the mask substrate, performing an etching process on a portion of the reflective layer on the black border area, after the etching process has been performed, performing a heat treatment process on the black border area.

### CROSS-REFERENCE TO RELATED APPLICATION

This application claims priority from Korean Patent Application No. 10-2025-0005940 filed on Jan. 15, 2025 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a reflective photomask and a method for manufacturing the same. More specifically, the present disclosure relates to a reflective photomask including a black border and a method for manufacturing the same.

### Description of Related Art

As a design rule of a semiconductor device is gradually reduced, a technique for forming smaller-sized patterns is required. In order to meet this technical requirement, an extreme ultraviolet lithography process using extreme ultraviolet (EUV) having a short wavelength as a light source may be used. In particular, in a mass production process of a nano-sized semiconductor device of 40 nm or smaller, extreme ultraviolet light having a wavelength of about 10 nm to about 14 nm may be used.

In this regard, since the extreme ultraviolet light is absorbed by most refractive optical materials, not a refractive optical system but a reflective optical system is used in the extreme ultraviolet lithography process. A reflective photomask used in the reflective optical system may include a mask substrate, a reflective layer deposited on the mask substrate, and an absorption layer deposited on the reflective layer. The absorption layer may transfer a pattern image by selectively absorbing the EUV light in a pattern area of the reflective photomask.

In addition, an edge area EA of the reflective photomask may be a non-pattern area in which no pattern image is formed. However, the EUV reflected from the edge area of the reflective photomask may invade to a pattern area of another shot adjacent to a shot of interest and adversely affect the pattern image transfer of the adjacent shot. In order to prevent this invasion, a black border with very low reflectivity may be formed along the edge of the pattern area.

### SUMMARY

A technical purpose to be achieved by the present disclosure is to provide a reflective photomask with improved productivity.

Another technical purpose to be achieved by the present disclosure is to provide a method for manufacturing a reflective photomask with improved productivity.

The technical purposes of the present disclosure are not limited to the technical purposes mentioned above, and other technical purposes not mentioned may be clearly understood by those skilled in the art from the following description.

According to an aspect of the present disclosure, there is provided a method for manufacturing a reflective photomask, the method comprises providing a mask substrate including a pattern area and a black border area surrounding the pattern area, forming a reflective layer on the mask substrate, performing an etching process on a portion of the reflective layer on the black border area, after the etching process has been performed, performing a heat treatment process on the black border area.

According to an aspect of the present disclosure, there is provided a method for manufacturing a reflective photomask, the method comprises providing a mask substrate including a pattern area and a black border area surrounding the pattern area, forming a reflective layer on the mask substrate, in which the reflective layer includes at least one first material layer and at least one second material layer alternately laminated on one another, and the first material layer and the second material layer have different refractive indices from each other, performing an etching process on a portion of the reflective layer on the black border area, in which after the etching process has been performed, a defect pattern including a portion of the first material layer and a portion of the second material layer remains on the black border area, and performing a heat treatment process on the defect pattern to form a residual pattern from the defect pattern, in which the residual pattern includes an intermixing layer of the first material layer and the second material layer.

According to an aspect of the present disclosure, there is provided a method for manufacturing a reflective photomask, the method comprises providing a mask substrate including a pattern area and a black border area surrounding the pattern area, forming a reflective layer on the mask substrate, whereon the reflective layer includes at least one first material layer and at least one second material layer alternately laminated on one another, in which the first material layer and the second material layer have different refractive indices from each other, forming an absorption layer on the reflective layer, performing a patterning process on a portion of the absorption layer on the pattern area, performing an etching process on a portion of the reflective layer on the black border area, in which after the etching process is performed, a defect pattern remaining as a portion of the reflective layer remains on the black border area, and performing a laser annealing process on the defect pattern.

It should be noted that the effects of the present disclosure are not limited to those described above, and other effects of the present disclosure will be apparent from the following description.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is a conceptual diagram for illustrating an extreme ultraviolet lithography apparatus using a reflective photomask according to some embodiments.

FIG. 2 is a schematic plan view for illustrating a reflective photomask according to some embodiments.

FIG. 3 is a schematic cross-sectional view taken along a line I-I of FIG. 2.

FIG. 4 is a flowchart illustrating a method for manufacturing a reflective photomask according to some embodiments.

FIGS. 5 through 8 are diagrams for illustrating intermediate structures corresponding to intermediate steps of a method for manufacturing a reflective photomask according to some embodiments.

FIGS. 9A through 9C are example diagrams for illustrating a residual pattern of a reflective photomask according to some embodiments.

FIG. 10 is a graph for illustrating an effect of a reflective photomask according to some embodiments.

FIG. 11 is a flowchart illustrating a method for manufacturing a reflective photomask according to some embodiments.

FIGS. 12 and 13 are diagrams of intermediate structures corresponding to intermediate steps of a method for manufacturing a reflective photomask according to some embodiments.

### DETAILED DESCRIPTIONS

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

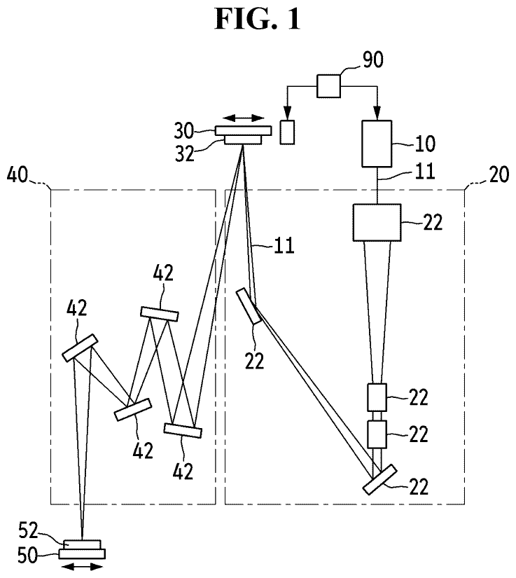

Hereinafter, a reflective photomask according to example embodiments will be described with reference to FIGS. 1 through 3.

FIG. 1 is a conceptual diagram for illustrating an extreme ultraviolet lithography apparatus using a reflective photomask according to some embodiments.

Referring to FIG. 1, the extreme ultraviolet lithography apparatus according to some embodiments may include an optical source 10, a light condenser 20, a projector 40, and a controller 90.

The light source 10 may generate light 11. In some embodiments, the light 11 may include extreme ultraviolet (EUV). For example, the light source 10 may generate the extreme ultraviolet light having a wavelength of about 13.5 nm using plasma generated by irradiating CO₂ laser to tin (Sn). The light 11 generated from the light source 10 may be provided to the light condenser 20.

The light condenser 20 may guide the light 11 (e.g., the extreme ultraviolet light) generated from the light source 10 toward a photomask 32. The photomask 32 may correspond to reflective photomasks to be described later according to some embodiments. That is, the reflective photomask according to some embodiments may be a reflective photomask for extreme ultraviolet rays. The light condenser 20 may include a condenser optics 22 (e.g., a lens and/or a mirror). The condenser optics 22 may condense and reflect the light 11 to guide the light toward the photomask 32. The light 11 may be obliquely incident on the photomask 32 through the light condenser 20.

In some embodiments, the photomask 32 may be moved while being mounted on a mask stage 30. The light source 10 and the mask stage 30 may be controlled by the controller 90.

The light 11 incident on the photomask 32 may be reflected from the photomask 32 and incident on the projector 40. The projector 40 may project a pattern image of the photomask 32 onto a target substrate 52. The target substrate 52 may be a wafer on which an integrated circuit is to be formed. For example, the target substrate 52 may include a photoresist film that reacts with the light 11. The projector 40 may include a projection optics 42 (e.g., a lens and/or a mirror). The projection optics 42 may reduce the pattern image on the photomask 32 by a predetermined magnification (e.g., 4 times, 6 times, or 8 times) using the light 11 reflected from the photomask 32, and may project the reduced pattern image onto the target substrate 52.

In some embodiments, the target substrate 52 may be mounted on a substrate stage 50. The substrate stage 50 may move the target substrate 52 to change an exposure area (or exposure position) of the target substrate 52.

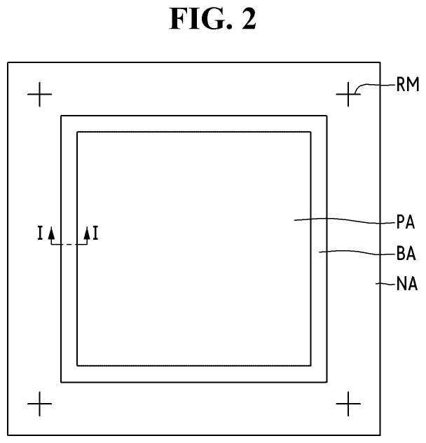

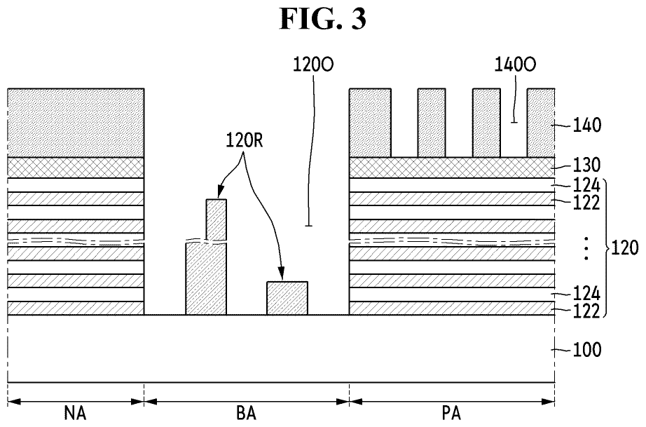

FIG. 2 is a schematic plan view for illustrating a reflective photomask according to some embodiments. FIG. 3 is a schematic cross-sectional view taken along a line I-I of FIG. 2.

Referring to FIGS. 2 and 3, the reflective photomask according to some embodiments may include a mask substrate 100, a reflective layer 120, a capping layer 130, an absorption layer 140, and a residual pattern 120R.

The mask substrate 100 may include a low thermal expansion material (LTEM) having a relatively low coefficient of thermal expansion. In addition, the mask substrate 100 may include a material having excellent smoothness and flatness, and may include a material having excellent resistance to a cleaning solution. For example, the mask substrate 100 may include at least one of synthetic quartz glass, quartz glass, alumina silicate glass, soda lime glass, SiO₂—TiO₂-based glass, and/or a combination thereof. However, the present disclosure is not limited thereto.

The mask substrate 100 may include a pattern area PA, a non-pattern area NA, and a black border area BA.

The non-pattern area NA may surround the pattern area PA. The black border area BA may be interposed between the pattern area PA and the non-pattern area NA. For example, as illustrated in FIG. 2, the pattern area PA may be substantially rectangular, and each of the black border area BA and the non-pattern area NA may have a frame shape in a plan view so as to surround the pattern area PA.

The pattern area PA may be an area for transferring a pattern image to the target substrate (e.g., 52 of FIG. 1), and the non-pattern area NA may be an area to which the pattern image is not transferred. The black border area BA may be an area with adjusted reflectivity to prevent extreme ultraviolet rays, reflected from outside a pattern area PA of the shot of interest, from overlapping with extreme ultraviolet rays reflected from a pattern area PA of an adjacent shot.

In some embodiments, a reference mark RM may be formed on the non-pattern area NA. The reference mark RM may be used as a reference point for specifying a position at which a processing process (e.g., a laser annealing process to be described later) on the reflective photomask according to some embodiments is performed. A position, shape, size, number, etc. of the reference mark RM are only examples, and are not limited to those shown. In some embodiments, unlike the illustrated example, the reference mark RM may be formed on the black border area BA or the pattern area PA.

The reflective layer 120 may be deposited on the mask substrate 100. The reflective layer 120 may be configured to reflect the light (e.g., 11 of FIG. 1) incident on the reflective photomask according to some embodiments therefrom. For example, an extreme ultraviolet light (EUV) reflectivity of the reflective layer 120 may be about 50% or greater. For example, the reflective layer 120 may have the reflectivity of the extreme ultraviolet light having a wavelength of about 13.5 nm in a range of about 60% to about 75%.

In some embodiments, the reflective layer 120 may include a distributed Bragg reflector (DBR). The distributed Bragg reflector may provide relatively high reflectivity and relatively low transmittance using constructive interference of Fresnel reflection. For example, the reflective layer 120 may have a multilayer structure in which at least one first material layer 122 and at least one second material layer 124 are alternately laminated on one another. The first material layer 122 and the second material layer 124 may have different refractive indices from each other in the extreme ultraviolet (EUV) region. For example, in the extreme ultraviolet region, the refractive index of the second material layer 124 may be greater than the refractive index of the first material layer 122. The number of times the first material layers 122 and the second material layers 124 are alternately laminated may be in a range of about 20 times to about 80 times. However, the present disclosure is not limited thereto. In some embodiments, the uppermost layer of the reflective layer 120 may be the second material layer 124.

In order to induce the constructive interference, a material and a thickness of each of the first material layer 122 and the second material layer 124 may be appropriately selected based on a wavelength of light (e.g., extreme ultraviolet light) incident on the reflective layer 120 and/or a target light (e.g., extreme ultraviolet light) reflectivity of the reflective layer 120. For example, the first material layer 122 may include a molybdenum (Mo) film, and the second material layer 124 may include a silicon (Si) film. For example, the thicknesses of each of the first material layer 122 and the second material layer 124 may be in a range of about 2 nm to about 5 nm.

The capping layer 130 may be deposited on the reflective layer 120. The capping layer 130 may be interposed between the reflective layer 120 and the absorption layer 140. The capping layer 130 may cover an upper surface of an uppermost layer (e.g., the second material layer 124) of the reflective layer 120. The capping layer 130 may prevent damage to the reflective layer 120 and surface oxidation of the reflective layer 120. The capping layer 130 may include, for example, ruthenium (Ru). However, the present disclosure is not limited thereto. In some embodiments, unlike that shown in the drawings, the capping layer 130 may be omitted.

The absorption layer 140 may be deposited on the capping layer 130 (or the reflective layer 120). The absorption layer 140 may be configured to absorb the light (e.g., 11 of FIG. 1) incident on the reflective photomask according to some embodiments. For example, the with EUV (extreme ultraviolet light) reflectivity of the absorption layer 140 may be about 20% or smaller. In one example, the absorption layer 140 may have the reflectivity of the extreme ultraviolet light having a wavelength of about 13.5 nm in a range of about 2% to about 3%.

The absorption layer 140 of the pattern area PA may include an opening 140O. The opening 140O may include an opening 140O exposing at least a portion of the capping layer 130 of the pattern area PA (or at least a portion of the reflective layer 120 of the pattern area PA). The light (e.g., 11 of FIG. 1) incident on the reflective photomask according to some embodiments may pass through the opening 140O and be reflected from the reflective layer 120. Thus, the absorption layer 140 may selectively absorb the extreme ultraviolet rays to transfer the pattern image. That is, the pattern image corresponding to the opening 140O of the absorption layer 140 may be projected onto the target pattern (e.g., 52 of FIG. 1).

The absorption layer 140 may include, for example, at least one of TaN, TaHf, TaHfN, TaBSi, TaBSiN, TaB, TaBN, TaSi, TaSiN, TaGe, TaGeN, TaZr, TaZrN, and/or a combination thereof. However, the present disclosure is not limited thereto.

The residual pattern 120R may be formed on the black border area BA. For example, a trench 120O may be formed along the black border area BA and on the mask substrate 100. The trench 120O may be formed by removing a portion of the reflective layer 120 on the black border area BA. The trench 120O may have, for example, a frame shape in a plan view so as to surround a portion of the reflective layer 120 on the pattern area PA. The residual pattern 120R may be formed in the trench 120O.

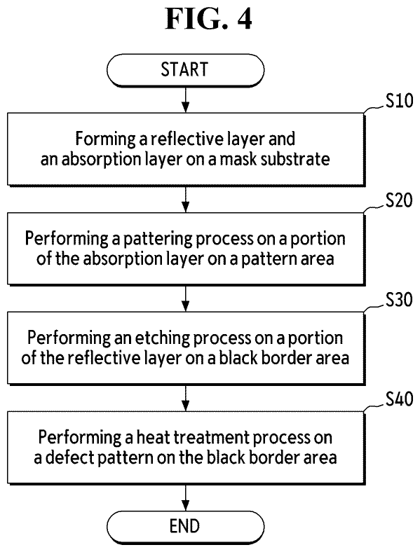

The residual pattern 120R may be formed by leaving a portion of the reflective layer 120 on the black border area BA. For example, the residual pattern 120R may include a material included in the reflective layer 120. In some embodiments, the residual pattern 120R may include an intermixing layer of the first material layer 122 and the second material layer 124. In some embodiments, the residual pattern 120R may further include a material included in the capping layer 130 and/or the absorption layer 140. The residual pattern 120R will be described in more detail later in the description about FIGS. 4 through 13.

The residual pattern 120R may have a reflectivity lower than that of the reflective layer 120 on the pattern area PA. For example, the extreme ultraviolet light reflectivity of the residual pattern 120R may be about 1% or smaller. In one example, the residual pattern 120R may have the reflectivity of the extreme ultraviolet light having a wavelength of about 13.5 nm in a range of about 0.1% or smaller. Accordingly, overlapping of the extreme ultraviolet rays due to the black border area BA may be prevented.

Hereinafter, a method for manufacturing a reflective photomask according to example embodiments will be described with reference to FIGS. 1 through 13.

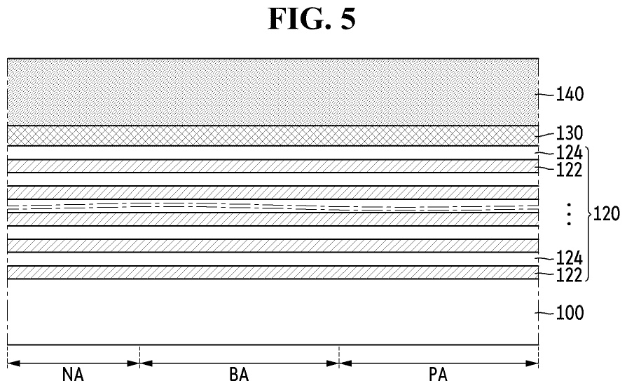

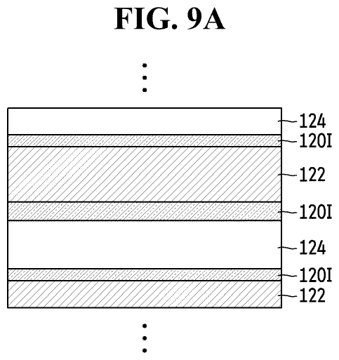

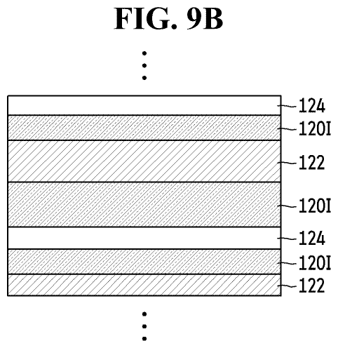

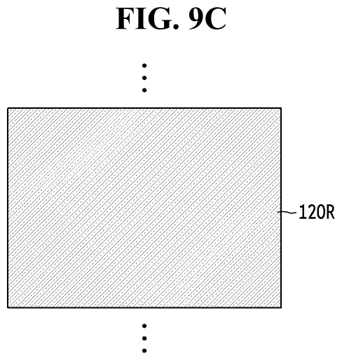

FIG. 4 is a flowchart illustrating a method for manufacturing a reflective photomask according to some embodiments. FIGS. 5 through 8 are diagrams for illustrating intermediate structures corresponding to intermediate steps of a method for manufacturing a reflective photomask according to some embodiments. FIGS. 9A through 9C are example diagrams for illustrating a residual pattern of a reflective photomask according to some embodiments. For convenience of description, contents duplicate with those as described above with reference to FIGS. 1 through 3 will be briefly described or descriptions thereof will be omitted.

Referring to FIGS. 4 and 5, the reflective layer 120 and the absorption layer 140 are formed on the mask substrate 100 in S10.

For example, the mask substrate 100 including the pattern area PA, the non-pattern area NA, and the black border area BA may be provided. Subsequently, the reflective layer 120, the capping layer 130, and the absorption layer 140 may be sequentially stacked on the mask substrate 100.

In some embodiments, the reflective layer 120 may include the first material layer 122 and the second material layer 124, which have different refractive indices. The first material layers 122 and the second material layers 124 may be alternately laminated on one another. For example, the first material layer 122 may include a molybdenum (Mo) film, and the second material layer 124 may include a silicon (Si) film.

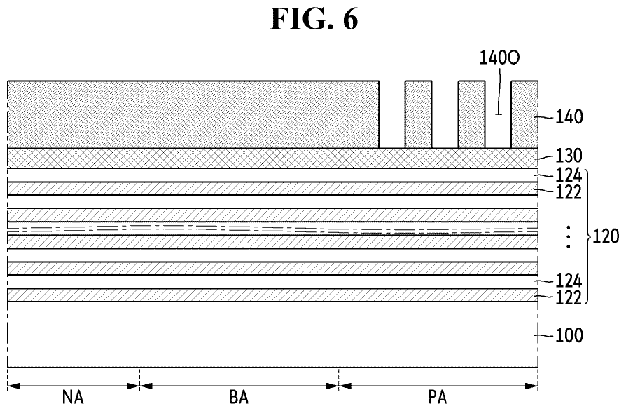

Referring to FIGS. 4 and 6, a patterning process is performed on the absorption layer 140 on the pattern area PA in S20.

For example, as the patterning process is performed, a portion of the absorption layer 140 on the pattern area PA may be removed to form the opening 140O. The opening 140O may define the pattern image projected onto the target pattern (e.g., 52 of FIG. 1). The patterning process may include, for example, a photolithography process. However, the present disclosure is not limited thereto.

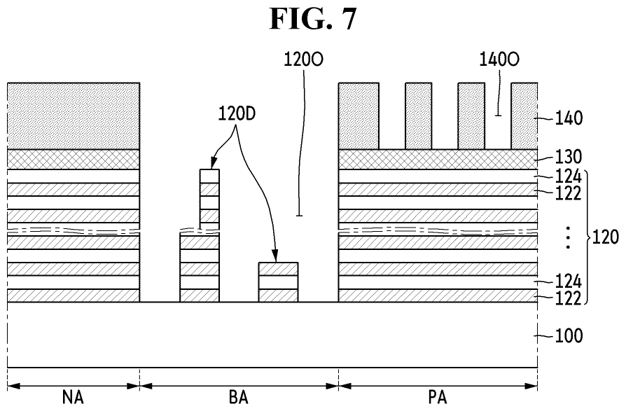

Referring to FIGS. 4 and 7, an etching process is performed on a portion of the reflective layer 120 on the black border area BA in S30.

For example, as the etching process is performed, a portion of the reflective layer 120, a portion of the capping layer 130, and a portion of the absorption layer 140 on the black border area BA may be removed to form the trench 120O. The etching process may include, for example, a multilayer etching process. However, the present disclosure is not limited thereto. The multilayer etching process may include, but is not limited to, reactive ion etching (RIE) and/or ion beam etching.

After the etching process has been performed, a defect pattern 120D may be formed on the black border area BA. For example, the defect pattern 120D may be formed in the trench 120O. The defect pattern 120D may be a portion of the reflective layer 120, a portion of the capping layer 130, and/or a portion of the absorption layer 140 remaining during the etching process. For example, the defect pattern 120D may include a portion of the first material layer 122 on the black border area BA and a portion of the second material layer 124 on the black border area BA. The position, shape, size (width or height), number, etc. of the defect pattern 120D are only examples, and are not limited to those shown.

As the defect pattern 120D includes the portion of the reflective layer 120, the defect pattern 120D may have a relatively high reflectivity. For example, the extreme ultraviolet light (EUV) reflectivity of the defect pattern 120D may be about 10% or higher.

Although it is illustrated that the defect pattern 120D includes only the portion of the reflective layer 120, this is only an example. In some embodiments, unlike the illustrated example, the defect pattern 120D may further include a portion of the capping layer 130 on the black border area BA and/or a portion of the absorption layer 140 on the black border area BA.

In some embodiments, after the etching process has been performed, an inspection process for determining whether the defect pattern 120D exists may be performed.

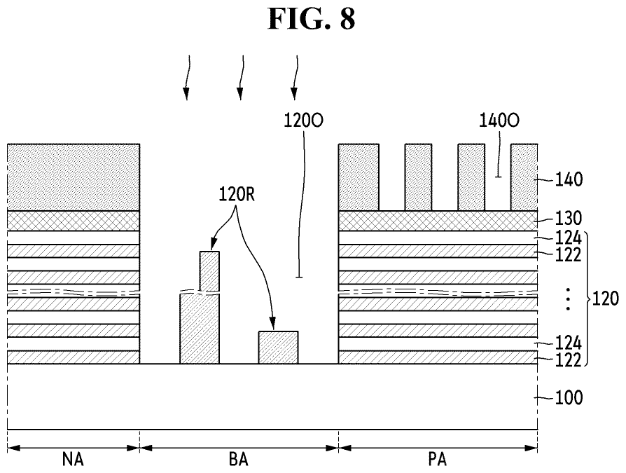

Referring to FIGS. 4 and 8, a heat treatment process is performed on the defect pattern 120D on the black border area BA in S40.

For example, an energy beam may be irradiated to the defect pattern 120D on the black border area BA. The energy beam may include, but is not limited to, at least one of an electron beam, a focused ion beam, a laser beam, an electromagnetic beam, and/or a combination thereof. For example, the heat treatment process may include a laser annealing process.

As the heat treatment process is performed, a heat-treated residual pattern 120R may be formed from the defect pattern 120D. The residual pattern 120R may have a reflectivity lower than a reflectivity of the defect pattern 120D. For example, when the defect pattern 120D includes amorphous silicon, a silicon layer of the defect pattern 120D may be crystallized due to an energy beam (e.g., a laser beam) irradiated to the defect pattern 120D, or the silicon layer of the defect pattern 120D may react with a surrounding metal material to form a metal silicide or may be diffused into a surrounding another material layer due to an energy beam (e.g., a laser beam) irradiated to the defect pattern 120D. Accordingly, properties of the material included in the defect pattern 120D may be changed, and thus the reflectivity thereof may be reduced. For example, the property (e.g., Bragg's condition) of the first material layer 122 and the second material layer 124 included in the defect pattern 120D may be changed, so that the constructive interference of Fresnel reflection may not be induced.

In some embodiments, the residual pattern 120R may have a higher density (or lower volume) than that of the defect pattern 120D. For example, due to an energy beam (e.g., a laser beam) irradiated to the defect pattern 120D, the residual pattern 120R having a smaller volume than that of the defect pattern 120D may be formed.

In some embodiments, the residual pattern 120R may include an intermixing layer of the first material layer 122 and the second material layer 124. For example, when the first material layer 122 includes a molybdenum (Mo) film and the second material layer 124 includes a silicon (Si) film, the residual pattern 120R may include both molybdenum (Mo) and silicon (Si). For example, the residual pattern 120R may include a compound (e.g., MoSi₂) of molybdenum (Mo) and silicon (Si). In some embodiments, the residual pattern 120R may include amorphous MoSi₂ (amorphous MoSi₂). In some embodiments, the residual pattern 120R may include hexagonal MoSi₂.

FIGS. 9A through 9C illustrate a process of forming the residual pattern 120R according to a heat treatment process in more detail.

Referring to FIG. 9A, an interface layer 120I may be formed between the first material layer 122 and the second material layer 124. The interface layer 120I may include an intermixing layer of the first material layer 122 and the second material layer 124. For example, when the first material layer 122 includes a molybdenum (Mo) film and the second material layer 124 includes a silicon (Si) film, the interface layer 120I may include both molybdenum (Mo) and silicon (Si). The interface layer 120I may be formed in a process of depositing the first material layer 122 and the second material layer 124. However, the present disclosure is not limited thereto. In some embodiments, the interface layer 120I may further include oxygen (O) due to oxidation of the first material layer 122 and/or the second material layer 124.

Next, referring to FIG. 9B, a laser annealing process may be performed on the first material layer 122 and the second material layer 124. During the laser annealing process, the interface layer 120I may be expanded. For example, a thickness of the first material layer 122 and/or a thickness of the second material layer 124 may be reduced, and a thickness of the interface layer 120I may be increased.

Subsequently, referring to FIG. 9C, the residual pattern 120R including the intermixing layer of the first material layer 122 and the second material layer 124 may be formed. In FIG. 9C, only a case in which the first material layer 122 and the second material layer 124 do not remain in the residual pattern 120R is illustrated. However, this is merely an example. In some embodiments, unlike that shown (e.g., as shown in FIG. 9B), the residual pattern 120R may include not only the intermixing layer of the first material layer 122 and the second material layer 124 but also the first material layer 122 and/or the second material layer 124.

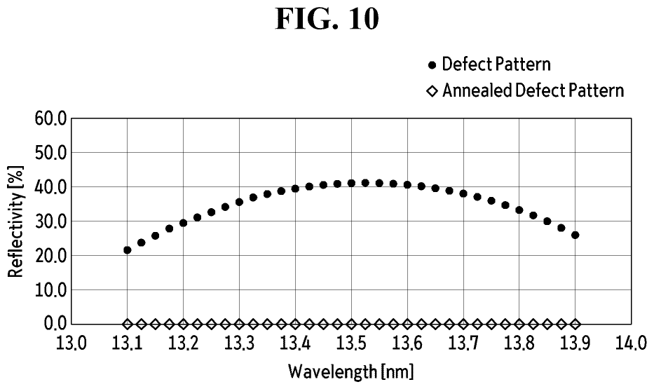

FIG. 10 is a graph for illustrating an effect of a reflective photomask according to some embodiments. For reference, in FIG. 10, an x-axis represents a wavelength of extreme ultraviolet light incident on the reflective photomask, and a y-axis represents an extreme ultraviolet light reflectivity of the reflective photomask. In addition, in FIG. 10, a defect pattern corresponds to the defect pattern 120D described above using FIG. 7, and an annealed defect pattern corresponds to the residual pattern 120R described above using FIG. 8.

Referring to FIG. 10, it may be identified that the annealed defect pattern has significantly reduced reflectivity compared to that of the defect pattern. Specifically, the defect pattern exhibits a reflectivity of the extreme ultraviolet light having a wavelength of 13.1 nm to 13.9 nm in a range of about 20% or greater. In contrast, the annealed defect pattern exhibits a reflectivity of the extreme ultraviolet light having a wavelength of 13.1 nm to 13.9 nm in a range of about 0.1% or smaller and thus exhibits the significantly lowered reflectivity.

In order to form the black border with reduced reflectivity in the reflective photomask, a technique of processing a multilayer structure of a reflective layer using an etching process has been proposed. However, in the etching process (e.g., a multilayer etching process) on the reflective layer, a portion of the reflective layer may remain, which may act as a defect that increases the reflectivity of the black border.

The method for manufacturing the reflective photomask according to some embodiments may remove the defect of the black border via the above-described heat treatment process. Specifically, as described above, the defect pattern 120D on the black border area BA may be converted into the residual pattern 120R under the heat treatment process (e.g., a laser annealing process), and the residual pattern 120R may have the significantly reduced reflectivity in the extreme ultraviolet region, and thus may not act as the defect. In addition, the heat treatment process has a relatively lower process difficulty than that of each of other processes (e.g., a repair process) for removing the defect pattern 120D. Accordingly, a turn around time (TAT) and process complexity may be reduced such that the reflective photomask having improved productivity and the method for manufacturing the same may be provided.

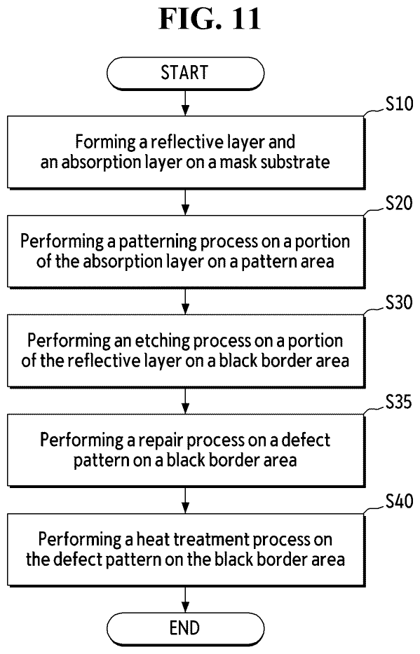

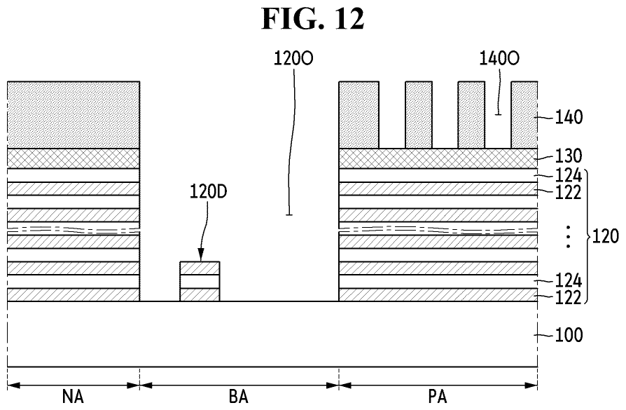

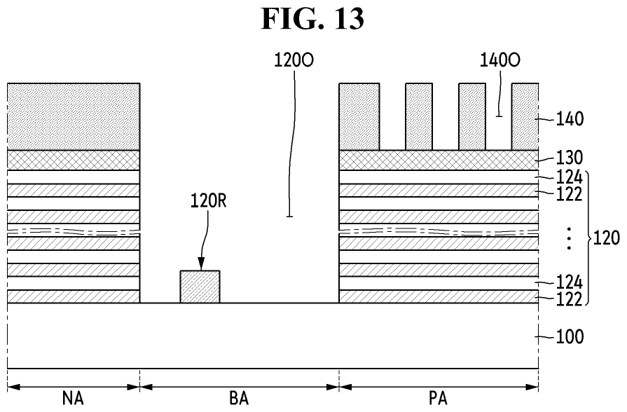

FIG. 11 is a flowchart illustrating a method for manufacturing a reflective photomask according to some embodiments. FIGS. 12 and 13 are diagrams of intermediate structures corresponding to intermediate steps of a method for manufacturing a reflective photomask according to some embodiments. For convenience of description, contents duplicate with those as described above with reference to FIGS. 1 through 10 will be briefly described or descriptions thereof will be omitted. For reference, FIG. 12 is a diagram of an intermediate structure corresponding to an intermediate step after FIG. 7.

Referring to FIGS. 11 and 12, after the etching process has been performed on the reflective layer 120 on the black border area BA in S30, a repair process is performed on the defect pattern 120D on the black border area BA in S35.

For example, a high power laser may be irradiated to the defect pattern 120D on the black border area BA. As the repair process is performed, at least a portion of the defect pattern 120D may be removed.

After the repair process has been performed, the defect pattern 120D may remain on the black border area BA. The remaining defect pattern 120D may be a portion or a fragment of the defect pattern 120D that is not removed during the repair process. The position, shape, size (width or height), number, and the like of the remaining defect patterns 120D are only examples, and are not limited to those shown.

Referring to FIGS. 11 and 13, a heat treatment process is performed on the defect pattern 120D on the black border area BA in S40.

As the heat treatment process is performed, a heat-treated residual pattern 120R may be formed from the defect pattern 120D. Since the formation of the residual pattern 120R may be similar to that as described above with reference to FIGS. 4 and 8, a detailed description thereof will be omitted below.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A method for manufacturing a reflective photomask, the method comprising:
providing a mask substrate including a pattern area and a black border area surrounding the pattern area;
forming a reflective layer on the mask substrate;
performing an etching process on a portion of the reflective layer on the black border area;
after the etching process has been performed, performing a heat treatment process on the black border area.

2. The method for manufacturing the reflective photomask of claim 1, wherein after the etching process has been performed, a defect pattern remaining as a portion of the reflective layer remains on the black border area,
wherein the heat treatment process is performed on the defect pattern.

3. The method for manufacturing the reflective photomask of claim 1, further comprising:
forming an absorption layer on the reflection layer,
performing a patterning process on a portion of the absorption layer on the pattern area.

4. The method for manufacturing the reflective photomask of claim 3, wherein the patterning process is performed before the etching process is performed.

5. The method for manufacturing the reflective photomask of claim 1, further comprising:
forming a capping layer on the reflective layer before the etching process is performed.

6. The method for manufacturing the reflective photomask of claim 1, wherein the reflective layer includes at least one first material layer and at least one second material layer alternately laminated on one another, wherein the at least one first material layer and the at least one second material layer have different refractive indices from each other.

7. The method for manufacturing the reflective photomask of claim 6, wherein the at least one first material layer includes a molybdenum (Mo) film,
wherein the at least one second material layer includes a silicon (Si) film.

8. The method for manufacturing the reflective photomask of claim 1, wherein the heat treatment process includes a laser annealing process.

9. The method for manufacturing the reflective photomask of claim 1, wherein the reflective photomask is a reflective photomask for extreme ultraviolet (EUV) light.

10. A method for manufacturing a reflective photomask, the method comprising:
providing a mask substrate including a pattern area and a black border area surrounding the pattern area;
forming a reflective layer on the mask substrate, wherein the reflective layer includes at least one first material layer and at least one second material layer alternately laminated on one another, wherein the at least one first material layer and the at least one second material layer have different refractive indices from each other;
performing an etching process on a portion of the reflective layer on the black border area, wherein after the etching process has been performed, a defect pattern including a portion of the at least one first material layer and a portion of the at least one second material layer remains on the black border area; and
performing a heat treatment process on the defect pattern to form a residual pattern from the defect pattern,
wherein the residual pattern includes an intermixing layer of the at least one first material layer and the at least one second material layer.

11. The method for manufacturing the reflective photomask of claim 10, wherein the at least one first material layer includes a molybdenum (Mo) film, and the at least one second material layer includes a silicon (Si) film.

12. The method for manufacturing the reflective photomask of claim 11, wherein the intermixing layer includes hexagonal MoSi₂.

13. The method for manufacturing the reflective photomask of claim 10, wherein an extreme ultraviolet (EUV) reflectivity of the defect pattern is 10% or greater.

14. The method for manufacturing the reflective photomask of claim 10, wherein an extreme ultraviolet (EUV) reflectivity of the residual pattern is 0.1% or lower.

15. The method for manufacturing the reflective photomask of claim 10, further comprising:
forming an absorption layer on the reflection layer,
performing a patterning process on a portion of the absorption layer on the pattern area.

16. The method for manufacturing the reflective photomask of claim 10, wherein the heat treatment process includes a laser annealing process.

17. A method for manufacturing a reflective photomask, the method comprising:
providing a mask substrate including a pattern area and a black border area surrounding the pattern area;
forming a reflective layer on the mask substrate, wherein the reflective layer includes at least one first material layer and at least one second material layer alternately laminated on one another, wherein the at least one first material layer and the at least one second material layer have different refractive indices from each other;
forming an absorption layer on the reflective layer;
performing a patterning process on a portion of the absorption layer on the pattern area;
performing an etching process on a portion of the reflective layer on the black border area, wherein after the etching process is performed, a defect pattern remaining as a portion of the reflective layer remains on the black border area; and
performing a laser annealing process on the defect pattern.

18. The method for manufacturing the reflective photomask of claim 17, further comprising forming a capping layer between the reflective layer and the absorption layer.

19. The method for manufacturing the reflective photomask of claim 17, wherein the at least one first material layer includes a molybdenum (Mo) film, and the at least one second material layer includes a silicon (Si) film.

20. The method for manufacturing the reflective photomask of claim 17, wherein in the laser annealing process, a residual pattern including an intermixing layer of the at least one first material layer and the at least one second material layer is formed from the defect pattern.
